(19) United States
(12) Patent Application Publication
(10) Pub. No.: US 2004/0175923 A1
(43) Pub. Date: Sep. 9, 2004

(54) Semiconductor device and fabrication thereof

(75) Inventor: Masaya Kawano, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 10/781,904

(22) Filed: Feb. 20, 2004

(30) Foreign Application Priority Data
Feb. 24, 2003 (JP) 45740/2003
Feb. 16, 2004 (JP) 37902/2004

(51) Int. Cl. H01L 21/4763

(52) U.S. Cl. 438/622

(57) ABSTRACT

The object of the present invention is to reduce, in the fabrication of a semiconductor device with a multi-layered interconnection, stresses imposed on conductive elements by interlayer dielectric films made of different materials.

For a given multi-layered semiconductor device in which a test conductive element is flanked by plural interlayer dielectric films made of different materials, stresses imposed on the test conductive element by the interlayer dielectric films are determined by calculation. The calculation is based on an equation involving an average thermal expansion coefficient of the dielectric films which is obtained from the thermal expansion coefficients of individual dielectric films and their relative volumes, the temperature at which a conductive material constituting the test conductive element undergoes stress relaxation, and the highest observable temperature during fabrication. Maximum temperature to be observed during fabrication and the materials and relative thicknesses of individual dielectric films are appropriately adjusted such that the stress value obtained by calculation is below a specified tolerable level which is known to cause no void formation around the test conductive element.

### BACKGROUND OF THE INVENTION

1. Field of the Invention

The present invention relates to a semiconductor device and fabrication thereof, particularly to a semiconductor device having a multi-layer interconnection, and fabrication thereof.

2. Description of the Prior Art

In recent years, the size of semiconductor chips carrying integrated circuits becomes compact. In this respect, the technique enabling multi-layered wiring on a chip attracts attention. In order to achieve multi-layered wiring on a chip, an insulating film must be interposed between adjacent upper and lower wiring layers and the two wiring layers be interconnected via interconnecting leads (vias) embedded in via holes formed through the insulating film. To achieve the highly dense integration of circuits, it is necessary to reduce the diameter of each via. However, if the diameter of each via is reduced extremely, stresses developed during fabrication processes between an inter-metal insulating film (dielectric film) and an adjacent wiring layer will concentrate around the thinned via, and may damage it.

A conventional technique proposes, to reduce such stresses developed between an inter-metal dielectric film and an adjacent wiring layer, a structure as shown in FIG. 1 where a fluorine-containing silicon oxide/nitride film is laid as a dielectric film over an aluminum-based wiring layer (Japanese Unexamined Patent Application Publication No. 7-169833).

According to this conventional technique, aluminum wires 203 are selectively arranged on a semiconductor substrate 201 with a dielectric film 202 interposed in between. Then, a fluorine-containing silicon oxide/nitride film 204 is laid over the assembly. This arrangement is introduced with a view to reduce stresses imposed on the aluminum wires 203, and to prevent thereby the aluminum wires from being interrupted, or undergoing the increase of resistance.

The above conventional technique intends to reduce-stresses developed between aluminum wires and the inter-metal dielectric film laid over the wires. However, stresses in question rather concentrate on vias which are implemented for interconnecting upper and lower wiring layers. Thus, a following problem may be brought about. Stresses which are themselves sufficiently low not to interfere with the normal functioning of wires may be transmitted from the wires to adjacent vias to concentrate there and cause the generation of voids there which in turn causes the resistance of the vias to be increased.

Generally, plural interlayer dielectric films may be made from different materials. A conventional technique for moderating stresses imposed on wires consists of changing as appropriate the material of an interlayer dielectric film adjacent to the wires which are most likely to be exposed to intensive stresses. However, unless stresses imposed by interlayer dielectric films at large on multiple wiring layers are sufficiently reduced, it will be impossible to achieve an improved and efficient installation of wiring layers on a chip.

The aforementioned document describes, in relation to a method for fabricating a multi-layered chip, it is possible to form any single interlayer dielectric film (specifically, one made of fluorine-containing silicon oxide/nitride) at 200° C. or lower. Assume that copper is used as a material of wires. If the copper wires are heated to a high temperature, they will be relieved of stresses as long as kept at that temperature (stress relaxation). As the temperature lowers, however, the copper wires will be exposed more or less to residual tensile stresses. For the stable functioning of wires, it is important to reduce the residual tensile stresses, and for this purpose it is necessary to lower maximum temperature observable during the fabrication process. Therefore, simply lowering the temperature necessary for the formation of one given interlayer dielectric film does not necessarily ensure the highly efficient and reliable fabrication of semiconductor chips with a multi-layered interconnection.

In addition, according to conventional methods, for evaluating stresses imposed on vias, it is necessary to introduce a three-dimensional simulation model and to make complicated calculations using the model, which is cumbersome.

The present invention specified in this application aims to provide a semiconductor device with a multi-layered interconnection during the fabrication of which stresses imposed by multiple interlayer dielectric films on conductive elements including vias are effectively reduced, and a method for fabricating such a multi-layered semiconductor device.

### SUMMARY OF THE INVENTION

The present invention provides a method for fabricating a semiconductor device comprising the steps of: forming a lower wiring layer on a semiconductor substrate; coating two or more layers of dielectric films over the lower wiring layer; forming a via hole and a groove through the dielectric films; and forming an upper wiring layer in the groove and a via in the via hole to connect the lower wiring layer with the upper wiring layer, wherein the maximum process temperature T_{process}_{_{—}}ₘₐₓ after forming the dielectric films or material of the dielectric films and relative thickness of the dielectric films are determined using following inequality (1):

$$( α - {α}_{diel}^{′} ) \frac{E}{1 - v} ( {T}_{process\_max} - T ) ≦ A , \qquad ( 1 )$$

where A represents critical stress value near the via, which is predetermined as a critical value causing voids near the via by a thermal treatment after forming the dielectric films, α represents a thermal expansion coefficient of the via and the upper wiring layer; α′_{diel} represents an average thermal expansion coefficient of the dielectric films calculated with their relative thickness; E represents an elastic coefficient of the via and the upper wiring layer; ν represents a Poisson's ratio of the via and the upper wiring layer; and T represents a stress relaxation temperature of the via and the upper wiring layer.

The present invention further provides a method for fabricating a semiconductor device, the lower wiring layer, upper wiring layer and via are made of metal.

The present invention further provides a method for fabricating a semiconductor device, the lower wiring layer, upper wiring layer are made of copper, and the maximum process temperature of the semiconductor device, combination of the materials and relative thicknesses of individual dielectric films are determined according to the inequality (1) using T=300° C., A=200 MPa.

The present invention further provides a method for fabricating a semiconductor device, wherein the upper wiring layer and the via are made of copper, and the maximum process temperature T_{process}_{_{—}}ₘₐₓ is equal to or lower than 450° C.

As seen from above, it is readily possible according to the method of the invention for fabricating a semiconductor device with a multi-layered interconnection to determine the highest tolerable temperature to be observed during the fabrication of the semiconductor device, by determining the stress imposed on conductive elements using the stress relaxation temperature, thermal expansion coefficient, elastic coefficient, and Poisson's ratio of the conductive metal, and the average thermal expansion coefficient of plural dielectric films with their relative volumes being taken into account.

Furthermore, it is readily possible according to the method of the invention to determine the most appropriate combination of the materials of the plural dielectric films and their relative thicknesses, by determining the stress imposed on conductive elements using the stress relaxation temperature, thermal expansion coefficient, elastic coefficient, and Poisson's ratio of the conductive metal, and maximum temperature observable during the fabrication of the semiconductor device.

### BRIEF DESCRIPTION OF THE DRAWINGS

The above and other objects, advantages and features of the present invention will be more apparent from the following description taken in conjunction with the accompanying drawings in which:

FIG. 1 is a sectional view of a semiconductor device introduced for illustrating a conventional technique;

FIG. 2 shows a table listing the constitutive materials of inter-metal dielectric films incorporated into multi-layered semiconductor devices, and their thermal expansion coefficients;

FIG. 3 is a sectional view of a (test) semiconductor device fabricated according to the method of the invention, and prepared for resistance measurement;

FIG. 4 gives a table listing the results of resistance measurement using test semiconductor devices;

FIG. 5 shows the change of resistance of test semiconductor devices with the materials of inter-metal dielectric layers being varied;

FIG. 6 shows a graph connecting stress and the change of resistance expected from the stress based on three-dimensional stress simulation;

FIG. 7 shows a graph connecting stress and the change of resistance expected from the stress based on the equation obtained in the present invention; and

FIG. 8 gives a table of numerical data indicating the relation of stresses due to inter-metal dielectric films with the temperature to which semiconductor devices are exposed with the materials of the inter-metal dielectric films being varied.

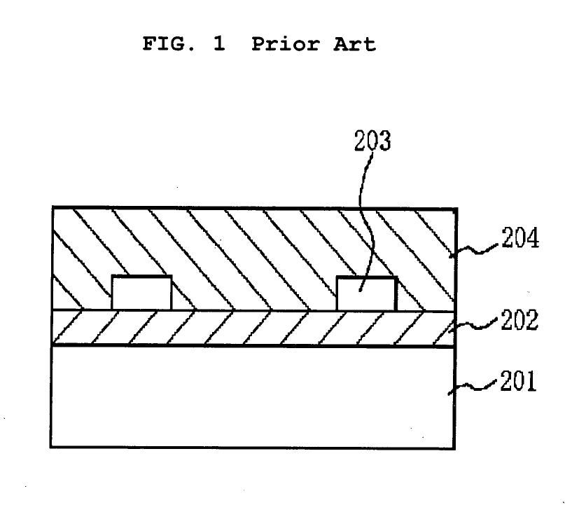

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The preferred embodiments of the present invention will be explained with reference to attached drawings. Generally, during the fabrication of a semiconductor device with a multi-layer interconnection, wiring layers (metal layers) and interconnecting leads (vias) made from copper (Cu) or an alloy mainly composed of copper are exposed to high temperatures, and wires and vias of copper are relieved of stresses when they are kept at a high temperature. However, when the temperature lowers, residual tensile stresses develop in the wires and vias which may lead to the generation of voids in the vias. Generation of voids in the vias may result in the interruption or increased resistance of the vias. This will seriously interfere with the highly efficient production of reliable devices. To reduce the residual tensile stresses, it is necessary to control the temperature to which the Cu-based conductive elements are exposed during the fabrication of the device. Therefore, even if it is made possible to reduce the temperature required for a certain step of the fabrication process, it will be useless in reducing overall residual stresses imposed on conductive elements during the fabrication process. It is more important to control maximum temperature observable during the fabrication of the device subsequent to the formation of Cu-based conductive elements.

To evaluate the resistance change of conductive elements in a multi-layered semiconductor device before and after thermal treatment, test multi-layered semiconductor devices were prepared with the materials of inter-metal dielectric films being varied. Each test semiconductor device included two metal wiring layers and a via made of copper or an alloy mainly composed of copper, the two metal wiring layers being connected in series to each other through the via. A thermal treatment was applied to each test semiconductor device, and the resistance across the two metal wiring layers was determined before and after the thermal treatment. The basic structure of each test semiconductor device submitted to the resistance measurement was as shown in FIG. 3. A first stopper layer 102 and a first inter-metal dielectric film 103 were formed on an interlayer dielectric film 101. The first stopper layer 102 and first inter-metal dielectric film 103 were pattern-etched such that a first metal layer 105 including a metal bump is formed on the interlayer dielectric film 101 with a first barrier layer 104 interposed in between. Then, a first cap layer 106 and a via insulating film 107 were formed over the first metal layer 105 and first inter-metal dielectric film 103. A second stopper layer 108 and a second inter-metal dielectric film 109 were formed then on the via insulating film 107. The first cap layer 106 and via insulating film 107 were pattern-etched such that a via hole was formed therethrough, and the second stopper layer 108 and second inter-metal dielectric film 109 were pattern-etched such that a cavity to receive a second metal bump was formed. A second metal layer 111 including the second metal bump was formed in the cavity to be connected to a via embedded in the via hole with a second barrier layer 110 interposed in between. Generally, in the fabrication of a multi-layered semiconductor device, multiple (one or more) metal layers are interposed as needed between a first cap layer 106 and a second metal layer 111. However, the test semiconductor device, because it is employed as an example to show the reliability of conductive elements prepared according to the method of the invention, includes a minimum number (two) of metal layers. Finally, a second cap layer 112 and a top insulating film 113 were formed over the second metal layer 111 and second inter-metal dielectric film 109.

A thermal treatment was applied to the test semiconductor devices prepared as above which were pattern-etched such that the first and second metal layers 105 and 111 made of copper were connected in series to each other through the via, and the resistance across the first and second metal layers was determined before and after the thermal treatment.

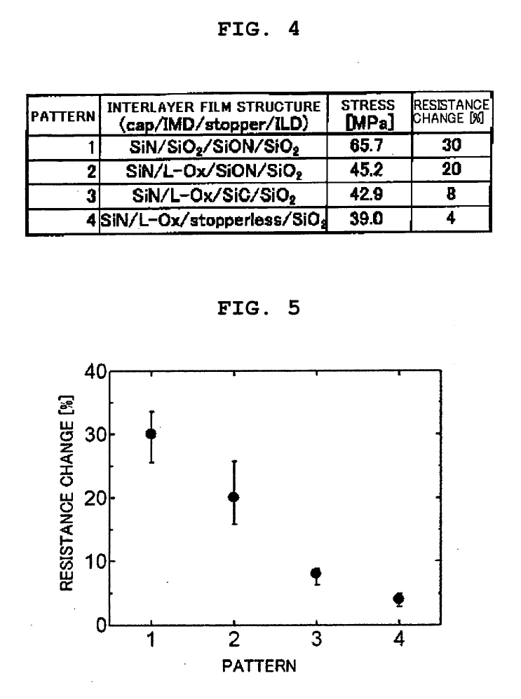

The thermal treatment consisted of heating the test semiconductor device at 400° C. for 30 minutes, and the resistance in question was determined before and after the thermal treatment. Then, the results as shown in FIG. 4 were obtained. A multi-layered semiconductor device includes the repetition of a unitary stack of insulating films. They are, with respect to the test semiconductor device, a fist cap layer (cap) 106, second inter-metal dielectric film (IMD) 109, second stopper layer (stopper) 108, and via insulating film (interlayer dielectric or ILD) 107. For brevity, the unitary stack is expressed as consisting of cap/IMD/stopper/ILD. The test semiconductor devices were prepared such that the materials constituting the individual layers of the unitary stack were different, and were distinguished according to the constitutive materials of the unitary stack. One unitary stack was expressed, for example, as SiN/SiO₂/SiON/SiO₂ (test pattern 1) which means that the unitary stack consists of a first cap layer (cap) of SiN, second inter-metal dielectric film (IMD) of SiO2, second stopper layer-(stopper) of SiON, and interlayer dielectric film (ILD) of SiO₂. In the same manner, test semiconductor devices in which the individual layers of the unitary stack are made of SiN/L-Ox/SiON/SiO₂ (test pattern 2), SiN/L-Ox/SiC/SiO₂ (test pattern 3), and SiN/L-Ox/no-stopper/SiO₂ (test pattern 4) were prepared, and submitted to the same test. The abbreviation “L-Ox” represents a film made of SIOH whose molecular structure takes a ladder-like form. (ladder-oxide (SiOH)). For each test semiconductor device, five samples were prepared. What is worthy of notice in this connection is that the inter-metal dielectric films under study, after the thermal treatment, impose stresses mainly onto the upper wiring layer and the via.

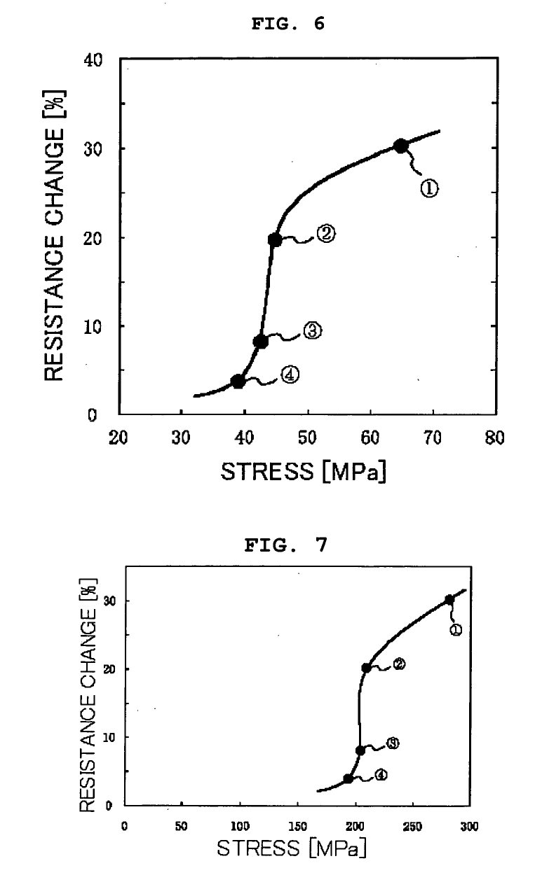

Inspection of the results shown in FIG. 4 reveals that the resistance increases 30% in the test devices with test pattern 1, 20% in those with test pattern 2, 8% in those with test pattern 3, and 4% in those with test pattern 4, after the thermal treatment. In a separate experiment using three-dimensional stress simulation, stresses imposed on the basal surface of the via were estimated for the test semiconductor devices which had been heated to 300° C. The resistance change after heating varied according to the materials constituting the individual layers of the unitary stack, or the test patterns of the unitary stack as seen from the graph shown in FIG. 5. A graph relating the stress with the resistance change is shown in FIG. 6.

It was revealed from these experimental results that the materials constituting the individual layers of the unitary stack significantly affect the resistance change here concerned.

The test semiconductor devices whose unitary stack was composed of the materials of test patterns 1, 2, 3 and 4 were kept at 23, 150, 250 and 300° C., and the resistance change before and after the heating was determined. For all the test semiconductor devices, heating at 300° C. for 150 hours or longer brought about a resistance change by about 1%, while heating at 250° C. or lower for 150 hours brought about no resistance change.

Samples showing a considerable resistance change after heating were closely inspected. It was found that there were slit-like voids at the junction between the via and the lower wiring layer.

From these results it was suggested that the resistance change after heating can be ascribed to the concentration of stresses caused by inter-metal dielectric films onto the via which causes voids to develop within the via, and that the stresses imposed on the via vary depending on-the materials constituting the inter-metal dielectric films.

Take, as an example, a layered structure which is obtained by coating a thin film over a substrate at a high temperature, and then leaving the assembly to be cooled. Generally, the stress imposed on the thin film can be expressed by the following equation (2) (Saito, T., Kawano, R. and Ueno, K., “3-D elasto-plasticity finite-element analysis of the stress-induced void in Cu-based fine damascene wiring of a ULSI,” Proceedings of Japanese Society for Machine Technology, (Division A), 69, 682 (2003), pp. 4-11).

$$( α - {α}_{sub} ) \frac{E}{1 - v} ( {T}_{proces} - T ) \qquad ( 2 )$$

where α_{sub} represents the thermal expansion coefficient of the substrate, and α, E and ν represent, respectively, the thermal expansion coefficient, elastic coefficient and Poisson's ratio of the thin film, and T_{process} represents the temperature at which the thin film is coated, and T represents the stress relaxation temperature. The term “stress relaxation temperature” of a material means a temperature at which stresses of the material are relaxed. In the equation, for simplicity, stresses actually observed in the film at the coating temperature are ignored.

Now, stresses imposed on a copper-based metal layer of a semiconductor device will be considered, when the device is exposed to a high temperature. As described above, a Cu-based metal layer of a semiconductor device is exposed to stresses imposed by inter-metal dielectric films whose materials are different. To exactly determine stresses imposed on a metal layer of a semiconductor device, it is necessary to determine the materials of individual inter-metal dielectric films involved, and to employ three-dimensional stress simulation using the material data. However, it is possible to determine, in a relative term, stresses imposed on a metal layer and a via connected thereto without resorting to three-dimensional stress simulation, by using a thermal expansion coefficient α′_{diel} or an average thermal expansion coefficient for all the inter-metal dielectric films involved, as described below. The average thermal expansion coefficient α′_{diel} is defined as a value obtained by multiplying, for each inter-metal dielectric film involved, its thermal expansion coefficient with its volume ratio, and summating the results for all the inter-metal dielectric films involved. Accordingly, if n inter-metal dielectric films are involved, the α′_{diel} will be: α′_{diel}=α₁×r₁+α₂×rₙ+ . . . +αₙ×r₂ where α₁, . . . , αₙ represent the thermal expansion coefficients of individual inter-metal dielectric films, and r₁, . . . , rₙ represent the volume ratios of the individual inter-metal dielectric films. Consider, as an illustration, a layered structure of two inter-metal dielectric films one having α₁=1.0 and r₁=1/3, and the other α₂=1.5 and r₂=2/3. Then, α′_{diel}=1.0×1/3+1.5×2/3=4/3=1.3

When a Cu-based wire is heated to 300° C. or higher, it undergoes plastic deformation and is relieved of stresses. However, when the heating temperature is below 300° C., plastic deformation and stress relaxation hardly occur. Therefore, if a Cu-based wire or a semiconductor including such a Cu-based wire is heated to 300° C. or higher during its fabrication, stress relaxation will ensue, and as the temperature lowers, inter-metal dielectric films will impose tensile stresses on the Cu-based wire. Thus, a Cu-based conductive element will undergo stress relaxation when heated to 300° C. or higher, and be subject to stresses which may result in the generation of voids with the lowering of temperature, as described above. Thus, it is important to interpret the stress observed in a semiconductor device in terms of the difference between T_{—process}_{_{—}}ₘₐₓ or maximum temperature observable during the fabrication process of the device and 300° C. or a threshold at which the risk of void generation in a Cu-based conductive element becomes real.

Taking these factors into consideration, it is possible to assess the stress a Cu-based conductive element receives from inter-metal dielectric films when the ambient temperature is in a range at which the risk of void formation is real, by the following equation (3):

$$( α - {α}_{diel}^{′} ) \frac{E}{1 - v} ( {T}_{process\_max} - 300 ) \qquad ( 3 )$$

where α′_{diel} represents a thermal expansion coefficient averaged for all the inter-metal dielectric films involved, a the thermal expansion coefficient of a Cu-based conductive element under study, E the elastic coefficient of the Cu-based conductive element, ν the Poisson's ratio of the Cu-based conductive element, and T_{process}_{_{—}}ₘₐₓ maximum temperature observable during the fabrication process.

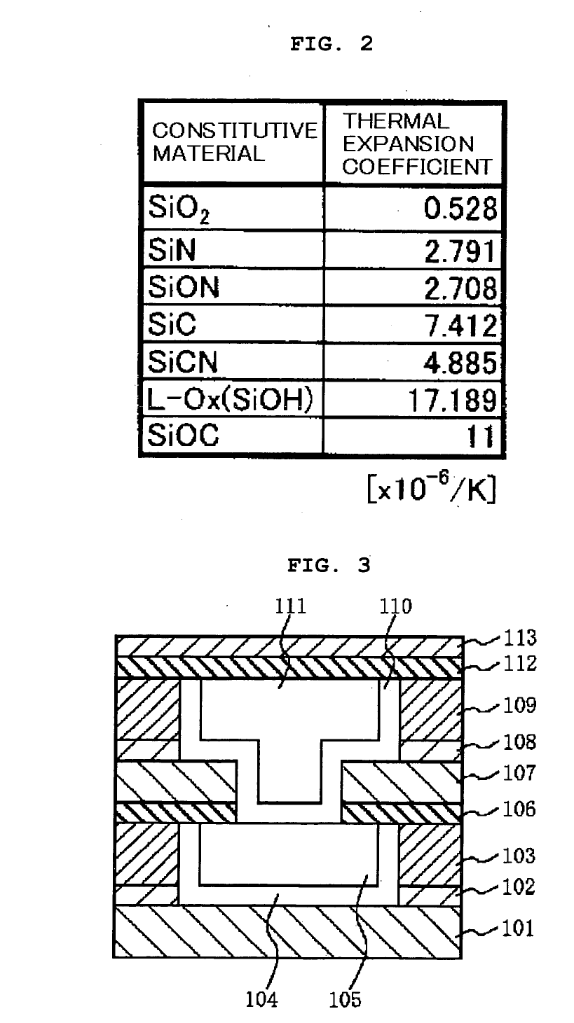

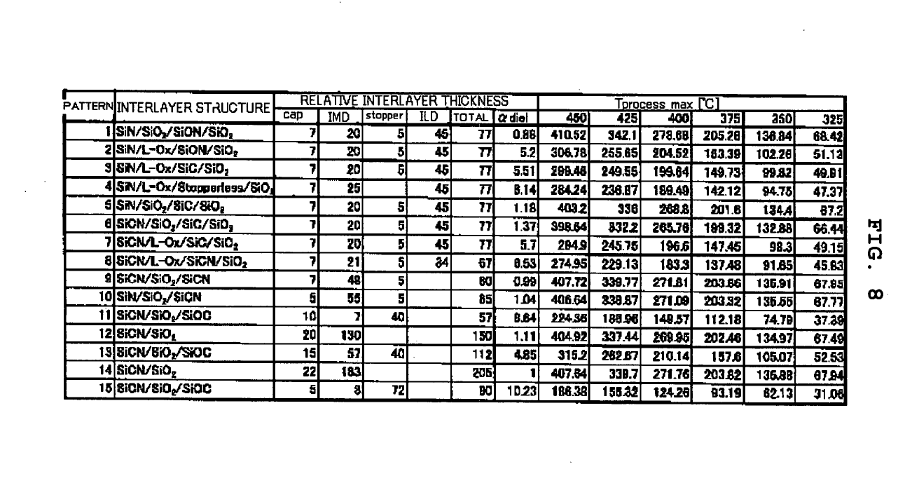

Some test semiconductor devices whose unitary stacks comprise layers made of different materials (test patterns 1 to 4) were chosen for the following study, and relevant data of inter-metal dielectric films (listed in the table of FIG. 8) were employed for the study. For each test semiconductor device, stresses imposed on a conductive element under study were determined on the assumption that the test device was heated to 400° C., and then annealed for. 30 minutes. The thermal expansion coefficient, elastic coefficient, and Poisson's ratio of copper or a metal material constituting the conductive element was assumed to be 18.0×10⁻⁶/K, 105 GPa, and 0.343 respectively (quoted from Chronological Scientific Tables, 2003, pp. 377-399, Maruzen Publishing Co.). The thermal expansion coefficient of the material used for the formation of each inter-metal dielectric film is listed in the table shown in FIG. 2. The averaged thermal expansion coefficients (α′_{diel}) of inter-metal dielectric films corresponding to test patterns 1, 2, 3 and 4 are 0.880, 5.20, 5.51 and 6.14, respectively. For this calculation, the volume fraction of a given inter-metal dielectric film was represented by its thickness, because all the inter-metal dielectric films were uniformly coated over the entire semiconductor chip surface. These values were introduced into the above equation, and stresses to be observed in the test semiconductor devices with test patterns 1 to 4 when T_{process}_{_{—}}ₘₐₓ was kept at 400° C., were calculated. They were found to be 274, 205, 200 and 189 MPa, respectively. These values were related with the respective resistance changes to give a graph shown in FIG. 7.

Comparison of the graph shown in FIG. 7 with that of FIG. 6 shows that the values derived from the above equation corresponds, in relative terms, with those based on three-dimensional stress simulation, that is, the two graphs are essentially the same when compared in relative terms. To trace the resistance change as a function of the absolute value of stress, the resistance change rises sharply at 43-44 MPa according to the results based on three-dimensional stress simulation, while the corresponding sharp rise occurs at 200 MPa according to the results obtained from the above equation. However, the two graphs are the same in that they show a sharp rise when the semiconductor device with test pattern 3 is replaced by the device with pattern 2. It is obvious from this that it will be possible to determine an appropriate fabrication process or the composition of inter-metal dielectric films by utilizing the equation (6) cited above, instead of three-dimensional stress stimulation which requires the construction of a model and cumbersome calculations on the model.

What is noteworthy in this connection is that, if the equation (6) is employed for the present purpose, and the materials constituting the inter-metal dielectric films and the relative thicknesses of those films are determined, the fabrication process or maximum temperature observable during fabrication, i.e., T_{process}_{_{—}}ₘₐₓ should be adjusted so as to allow the stress in question to be below 200 MPa, instead of 43 to 44 MPa which is required when three-dimensional stress simulation is employed. Then, the resistance increase of conductive elements subsequent to the fabrication process can be reduced to a tolerable level.

Conversely, if maximum temperature observable in a fabrication process is determined, it is possible to determine the appropriate materials of individual inter-metal dielectric films, and their relative thicknesses by using the equation.

Using the above equation, stresses developed in test semiconductor devices comprising inter-metal dielectric films made of specified materials were calculated, with maximum temperature to which the devices are exposed during their fabrication being varied. For example, if a test semiconductor device incorporating inter-metal dielectric films constituted of materials corresponding to pattern 11 is heated to 450° C., stresses imposed by the inter-metal dielectric films will be 224 MPa which may cause the generation of voids in the via. However, if maximum temperature to which the same semiconductor device is exposed during its fabrication is reduced to 425° C., the stresses in question will be 187 MPa which hardly causes stresses sufficiently large to evoke voids in the via. What is noteworthy in this connection is that copper rapidly softens when heated above 450° C., and thus the reliability of copper-based conductive elements is seriously affected when they are heated above 450° C. Specifically, when a semiconductor device is heated to 450° C. or higher, copper-based conductive elements thereof may have their resistance abnormally increased or be interrupted, and thus the yield of such semiconductor devices will be reduced. Therefore, it is necessary to maintain maximum temperature observable during the fabrication process at 450° C. or lower, regardless of which materials are employed for constructing the inter-metal dielectric films of the semiconductor device, as long as conductive elements are made of a metal mainly composed of copper.

To estimate the stresses to be evoked in a test semiconductor device using the above equation, it was assumed that the device comprises copper-based conductive elements, and 300° C. was used as the stress relaxation temperature of copper. However, the temperature at which stress relaxation occurs varies depending on the metal used as a material of conductive elements. For generalization, if T is used for expressing the temperature at which the stress relaxation of a given metal occurs, then the inequality (4) will be obtained:

$$( α - {α}_{diel}^{′} ) \frac{E}{1 - v} ( {T}_{process\_max} - T ) ≦ A \qquad ( 4 )$$

Each of the test semiconductor devices described above includes two wiring layers. However, the equation of the invention can be applied in the same manner as above to multi-layered semiconductor devices including one or more wiring layers, as long as the multi-layered devices consist of the repetition of a unit substructure.

With regard to the above test semiconductor devices, the upper wire layer and the via were connected via dual damascene process. However, the method of the invention can be applied to similar semiconductor devices whether different wiring layers are connected via single or dual damascene process, as is seen from the additional embodiments below.

With regard to the foregoing embodiment based on the test semiconductor devices, attention was mainly paid to the stresses on the via imposed by the dielectric films flanking the via. A second embodiment includes a layered substructure comprising the interlayer dielectric film 101, first stopper layer 102, and first inter-metal dielectric film 103 flanking the lowest wiring layer or first metal layer 105. It is possible to determine stresses imposed on the lowest wiring layer and the via by the dielectric films here concerned based on α′_{diel} or a thermal expansion coefficient averaged for those dielectric films. If the stress value thus obtained is considered in conjunction with the value obtained in the foregoing embodiment, it will be possible to estimate stresses imposed on the conductive elements more accurately. In addition, a third embodiment may be introduced which includes interlayer dielectric films (not illustrated) flanking the upper wiring layer, to determine stresses imposed on the upper wiring layer by the interlayer dielectric films based on a thermal expansion coefficient averaged for the dielectric films here concerned.

A fourth embodiment may be introduced which includes a layered substructure comprising the first stopper layer 102, first inter-metal dielectric film 103, first cap layer 106, and via insulating film 107, i.e., dielectric films flanking the via. Then, it is possible to determine stresses imposed on the via by those dielectric films based on a thermal expansion coefficient averaged for the dielectric films.

In the first embodiment, the test semiconductor devices include conductive elements made of copper or a metal mainly composed of copper. However, the conductive element may be made of a conductive material other than copper. Then, the elastic coefficient, Poisson's ratio, thermal expansion coefficient and stress relaxation temperature must be changed according to the altered conductive material. In the first embodiment, all the conductive elements are made of copper or an alloy mainly composed of copper. However, the method of the invention can be applied for the high-yield fabrication of semiconductor devices in which conductive elements are made of different conductive materials, for example, for the fabrication of semiconductor devices in which wires are made of copper and vias are made of tungsten.

As described above, according to the method of the invention, it is possible to readily estimate, for a semiconductor device with a multi-layered interconnection, stresses imposed on conductive elements by interlayer dielectric films during fabrication, and to properly adjust factors involved in the formation of voids around vias so that the interruption or resistance increase of conductive elements during fabrication can be safely prevented, the factors including, e.g., maximum temperature observable during fabrication, and the materials of individual dielectric films and relative thicknesses of those films. According to the method of the invention, it is possible, even for multi-layered semiconductor devices in which a via is flanked by multiple dielectric films, to determine maximum temperature to be observed during fabrication, and the appropriate materials of individual dielectric films and relative thicknesses of those films that ensure the stable fabrication of the semiconductor devices in which the via is relieved of resistance change during fabrication, and thus to reliably fabricate multi-layered semiconductor devices at high yield.

It is apparent that the present invention is not limited to the above embodiments, but may be modified and changed without departing from the scope of the invention.

What is claimed is:

1. A method for fabricating a semiconductor device comprising the steps of:
forming a lower wiring layer on a semiconductor substrate;
coating two or more layers of dielectric films over the lower wiring layer;
forming a via hole and a groove through the dielectric films; and
forming an upper wiring layer in the groove and a via in the via hole to connect the lower wiring layer with the upper wiring layer,
wherein the maximum process temperature T_{process}_{_{—}}ₘₐₓ after forming the dielectric films is determined using following inequality (1):
$$( α - {α}_{diel}^{′} ) \frac{E}{1 - v} ( {T}_{process\_max} - T ) ≦ A , \qquad ( 1 )$$
where A represents critical stress value near the via, which is predetermined as a critical value causing voids near the via by a thermal treatment after forming the dielectric films,
α represents a thermal expansion coefficient of the via and the upper wiring layer;
α′_{diel} represents an average thermal expansion coefficient of the dielectric films calculated with their relative thickness;
E represents an elastic coefficient of the via and the upper wiring layer;
ν represents a Poisson's ratio of the via and the upper wiring layer; and
T represents a stress relaxation temperature of the via and the upper wiring layer.

2. A method for fabricating a semiconductor device according to claim 1,
wherein the upper wiring layer and the via are made of metal.

3. A method for fabricating a semiconductor device according to claim 2,
wherein the upper wiring layer and the via are made of copper, and
the maximum process temperature is determined according to the inequality (1) using T=300° C. and A=200 MPa.

4. A method for fabricating a semiconductor device according to claim 2,
wherein the upper wiring layer and the via are made of copper, and
the maximum process temperature T_{process}_{_{—}}ₘₐₓ is equal to or lower than 450° C.

5. A method for fabricating a semiconductor device comprising the steps of:
forming a lower wiring layer on a semiconductor substrate;
coating one or more layers of dielectric films over the lower wiring layer;
forming a via hole and a groove through the dielectric films; and
forming an upper wiring layer in the groove and a via in the via hole to connect the lower wiring layer with the upper wiring layer,
wherein combination of materials of the dielectric films and relative thickness of the dielectric films are determined based on α′_{diel} calculated by following inequality (2):
$$( α - {α}_{diel}^{′} ) \frac{E}{1 - v} ( {T}_{process\_max} - T ) ≦ A , \qquad ( 2 )$$
where A represents critical stress value near the via, which is predetermined as a critical value causing voids near the via by thermal treatment after forming the upper wiring layer,
α represents a thermal expansion coefficient of the via and the upper wiring layer;
α′_{diel} represents an average thermal expansion coefficient of the dielectric films calculated with their relative thickness;
E represents an elastic coefficient of the via and the upper wiring layer;
ν represents a Poisson's ratio of the via and the upper wiring layer;
T_{process}_{_{—}}ₘₐₓ represents maximum process temperature of the semiconductor device after forming the upper wiring layer; and
T represents a stress relaxation temperature of the via and the upper wiring layer.

6. A method for fabricating a semiconductor device according to claim 5,
wherein the upper wiring layer and the via are made of metal.

7. A method for fabricating a semiconductor device according to claim 6,
wherein the upper wiring layer and the via are made of copper, and
the combination of materials of the dielectric films and the relative thickness of the dielectric films are determined based on α′_{diel} calculated by the inequality (2) using T=300° C. and A=200 MPa.

8. A method for fabricating a semiconductor device according to claim 6,
wherein the upper wiring layer and the via are made of copper, and
the maximum process temperature T_{process}_{_{—}}ₘₐₓ is equal to or lower than 450° C.

9. A semiconductor device comprising:
a lower wiring layer formed on a semiconductor substrate;
two or more layers of dielectric films formed over the lower wiring layer;
a via hole and a groove provided through the dielectric films;
an upper wiring layer formed in the groove; and
a via formed in the via hole to connect the lower wiring layer with the upper wiring layer, wherein the maximum process temperature T_{process}_{_{—}}ₘₐₓ after forming the dielectric films or materials of the dielectric films and relative thickness of the dielectric films are determined using following inequality (3):
$$( α - {α}_{diel}^{′} ) \frac{E}{1 - v} ( {T}_{process\_max} - T ) ≦ A , \qquad ( 3 )$$
where A represents critical stress value near the via, which is predetermined as a critical value causing voids near the via by a thermal treatment after forming the dielectric films,
α represents a thermal expansion coefficient of the via and the upper wiring layer;
α′_{diel} represents an average thermal expansion coefficient of the dielectric films calculated with their relative thickness;
E represents an elastic coefficient of the Via and the upper wiring layer;
ν represents a Poisson's ratio of the via and the upper wiring layer; and
T represents a stress relaxation temperature of the via and the upper wiring layer.

10. A semiconductor device according to claim 9,
wherein the upper wiring layer and the via are made of metal.

11. A semiconductor device according to claim 10,
wherein the upper wiring layer and the via are made of copper, and
the maximum process temperature is determined according to the inequality (1) using T=300° C. and A=200 MPa.

12. A semiconductor device according to claim 10,
wherein the upper wiring layer and the via are made of copper, and
the maximum process temperature T_{process}_{_{—}}ₘₐₓ is equal to or lower than 450° C.

13. A semiconductor device according to claim 9,
at least one layer of the dielectric films is made of ladder-oxide.

14. A semiconductor device according to claim 13,
at least one layer of the other dielectric films is made of SiC.
